(19) United States
(12) Patent Application Publication
(10) Pub. No.: US 2022/0415861 A1
(43) Pub. Date: Dec. 29, 2022

(54) COLOR OPTOELECTRONIC SOLID STATE DEVICE

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 17/767,774

(22) PCT Filed: Oct. 9, 2020
(86) PCT No.: PCT/CA2020/051363

§ 371 Date: Apr. 8, 2022

Related U.S. Application Data
(60) Provisional application No. 62/913,795, filed on Oct. 11, 2019.
(60) Provisional application No. 62/924,450, filed on Oct. 22, 2019.

(51) Int. Cl. H01L 25/075; H01L 33/60; H01L 33/62

(52) U.S. Cl. CPC H01L 25/0753; H01L 33/60; H01L 33/62; H01L 2933/0066

(57) ABSTRACT

Structures and methods are disclosed for fabricating a color optoelectronic solid state array device. In one embodiment, different color devices are combined to form a color optoelectronic solid state array. The micro device array comprises stacked layers, monolithic devices and backplanes. In addition, reflectors, image sources, light sensors and dichroic mirrors have been integrated.

### FIELD OF THE INVENTION

The present disclosure relates to optoelectronic solid state array devices and more particularly relates to forming color arrays of microdevices using different microdevices.

### SUMMARY

This invention relates to a microdevice array having a microdevice comprising, stacked layers of a semiconductor bonded to a backplane, pads in the backplane defining sub pixels, with multiple sub pixels for a pixel in an array of pixels, and the stacked layers bonded to the pads in the backplane defining sub pixels.

In an extension of the embodiment, the invention further relates to the microdevice array where it is a part of more than one microdevice array. Additionally, the microdevice array comprises a second stacked layer bonded to the backplane on top of a first stacked layer where the pads in the backplane define the sub pixels.

In a further extension a third stacked layer is bonded to the backplane on top of the second stacked layer where the pads in the backplane define the sub pixels.

In another embodiment, the invention discloses a method to modulate resistance in a color microdevice array, the method comprising, having more than one type of microdevices per pixel, sharing at least one type of microdevice between two adjacent pixels; and modulating a resistance of contact layers of the microdevice to create pixelation.

In another embodiment the invention discloses a method to fabricate a color microdevice array, the method comprising, stacking more than one layer of monolithic device on top of a backplane, bonding a first monolithic device to the backplane through a first pad, forming an opening in the first monolithic device, forming a second pad in the opening in the first monolithic device and bonding a second monolithic device to the backplane through the second pad.

In another embodiment the invention discloses method to combine light colors in a color microdevice array, the method comprising, combining light colors from different image sources using a linear color combinator, having the image sources on one side of linear color combinator; redirecting light generated by different image sources using a reflector, having a frontplane for image sources to produce or capture a light per pixel, having a backplane for controlling or extracting the output of the frontplane per pixel and coupling the image sources to fewer than two surfaces of the linear color combinator.

### BRIEF DESCRIPTION OF THE DRAWINGS

The foregoing and other advantages of the disclosure will become apparent upon reading the following detailed description and upon reference to the drawings.

FIG. 1 shows a pixel structure that the red microLED is larger.

FIG. 2 shows a pixel structure with one shared monolithic microdevice.

FIG. 3 shows a pixel structure with more than one shared monolithic microdevice.

FIG. 4 shows stacking structure of different microdevice arrays to form a color array.

FIG. 5 shows the existing approach on using dichroic prisms to form color displays.

FIG. 6 shows an embodiment using serial dichroic optics to form a color array.

FIG. 7 shows a top view of individual arrays used in serial dichroic optics.

FIG. 8 shows the structure of using different types of the same microdevices to form a better performing color array.

FIG. 9A shows one of the microdevices (array) formed as continuous pixelation.

FIG. 9B shows microdevices bonded to the pads.

FIG. 10A shows one of the microdevices (array) formed as continuous pixelation with optical VIA's on the second stacked layer and a bump having a microdevice.

FIG. 10B shows microdevices in FIG. 10,k bonded to the backplane.

FIG. 11A shows three stacked layers of semiconductor with a microdevice array.

FIG. 11B shows two stacked layers bonded together with the top layer having optical VIA's.

FIG. 11C shows three stacked layers bonded together with the top layer having optical VIA's.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “micro device” are used interchangeably. However, it is clear to one skilled in the art that the embodiments described here are independent of the device size.

The present disclosure is related to micro device array, wherein the micro device array may be bonded to a backplane with a reliable approach. The micro devices are fabricated over a micro device substrate. The micro device substrate may comprise micro light emitting diodes (LEDs), inorganic LEDs, organic LEDs, sensors, solid state devices, integrated circuits, microelectromechanical systems (MEMS), and/or other electronic components. The substrate may be the native substrate of the device layers or a receiver substrate where device layers or solid state devices are transferred to. Although microLED and display may have been used to explain an invention, the same technique can be used for other applications.

The backplane (or system) substrate may be any substrate and can be rigid or flexible. The backplane substrate may be made of glass, silicon, plastics, or any other commonly used material. The backplane substrate may also have active electronic components such as but not limited to transistors, resistors, capacitors, or any other electronic component commonly used in a system substrate. In some cases, the system substrate may be a substrate with electrical signal rows and columns. The backplane substrate may be a backplane with circuitry to derive micro devices.

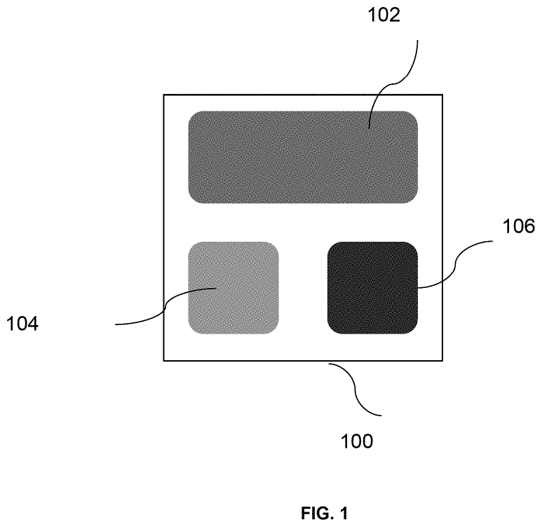

In most microdevice structures, the devices associated with higher wavelengths have lower performance. In one embodiment shown in FIG. 1, a pixel structure 100 is used where the microdevice 102 associated with larger wavelength is larger than the other microdevices 104 and 106.

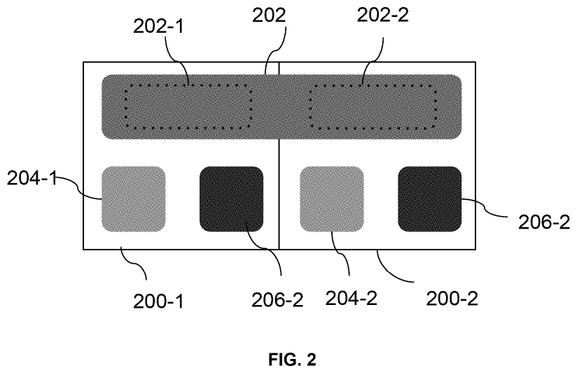

In another pixel structure 200-1 and 200-2, as shown in FIG. 2, the device 202 more sensitive to size reduction compared to other devices 204-1, 204-2, 206-1 and 206-2, is shared between two adjacent pixels. To create further pixelation, the device 202 is modified to have individual device effects 202-1 and 202-2. In one case, the modification is done by using two independent contacts for each sub device 202-1 and 202-2. Furthermore, one can modify the resistance of the doped layers between the two contacts for the sub devices. In the case of flip chip structure, one common contact can be used for the sub devices in the monolithic device.

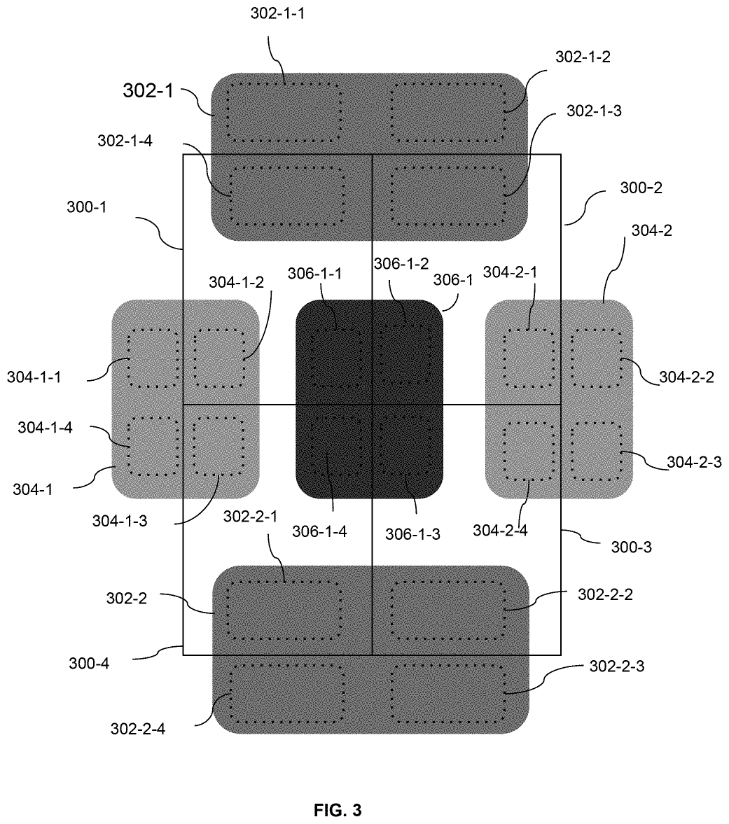

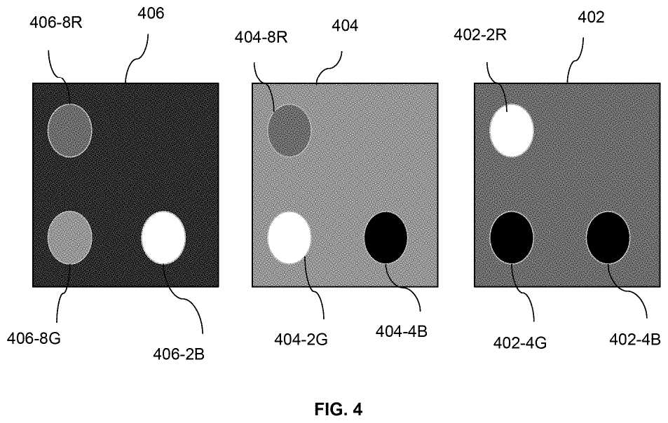

In another pixel structure defined by 300-1, 300-2, 300-3, and 300-4, as shown in FIG. 3, the pixel orientation is changed so that the devices of the same type are in the same places. Therefore, a monolithic device defined by 302-1, 302-2, 304-1, 304-2, and 306-I can be used for the same device in the adjacent pixel. To create further pixelation, the device 302-1, 302-2, 304-1, 304-2, 306-1, is modified to have individual device effect 302-1-1 to 302-1-4, 302-2-1 to 302-2-4, 304-1-1 to 304-1-4. 304-2-1 to 304-2-4, 306-1-1 to 306-1-4. In one case, the modification is done by using two independent contacts for each sub device 302-1-1 to 302-1-4, 302-2-1 to 302-2-4, 304-1-1 to 304-1-4.304-2-1 to 304-2-4, 306-1-1 to 306-1-4. Furthermore, one can modify the resistance of the doped layers between the two contacts for the sub devices 302-1-1 to 302-1-4, 302-2-1 to 302-2-4, 304-1-1 to 304-1-4, 304-2-1 to 304-2-4, 306-1-1 to 306-1-4. To reduce the effect of pixel orientation variation, a light/color diffuser structure can be developed on top of each pixel. This structure can be a lens or a patterned transparent layer.

In another approach a monolithic device is used for more than one pixel and to achieve color different devices are stacked on top of each other.

Here, the monolithic devices are turned to different pixelation by modulating the contact layer(s) resistance. Furthermore, the modulation of the contact layer(s) resistance, may create a higher resolution sub device array compared to the pads on the backplane for each device. This enables lower alignment accuracy needed for connecting the devices to the backplane. A first monolithic device (array) 402 is transferred to a substrate (backplane or temporary or another monolithic device(array). The first monolithic device 402 has a connection pad 402-2R that will be bonded to the respective pad on the backplane. Then areas 402-4G and 402-4B associated with the pads for the other device (array) are opened in the said transferred monolithic device 402 (array). The openings 402-4G and 402-4B are passivated and filled to form a pad for the next device 404 (array). Before or after the opening, or at the same time as filling the opening, a common electrode may get deposited for the first transferred monolithic device. Then, the second device 404 (array) is transferred (or bonded) to the said first transferred monolithic device (array) 402. The said second monolithic device 404 also has a connection pad 404-2G and opening 404-4B for the third device (if needed).

The second device can be a monolithic device or a simulated device. If the second device 404 is monolithic, there can be opening 404-8R also on the second device associated with the active area of the first monolithic device 402.

The opening 404-4B is passivated and filled to form a pad for the next device 406 (array). Before or after the opening, or at the same time as filling the opening, a common electrode may get deposited for the first transferred monolithic device. Then, the third device 406 (array) is transferred (or bonded) to the said second transferred monolithic device (array) 404. The said third device 406 also has a connection pad 406-2B.

The third device can be a monolithic device or a simulated device. If the third device 406 is monolithic, there can be openings 406-8R and 406-8G also on the third device 406 associated with the active area of the first device 402 and second device 404.

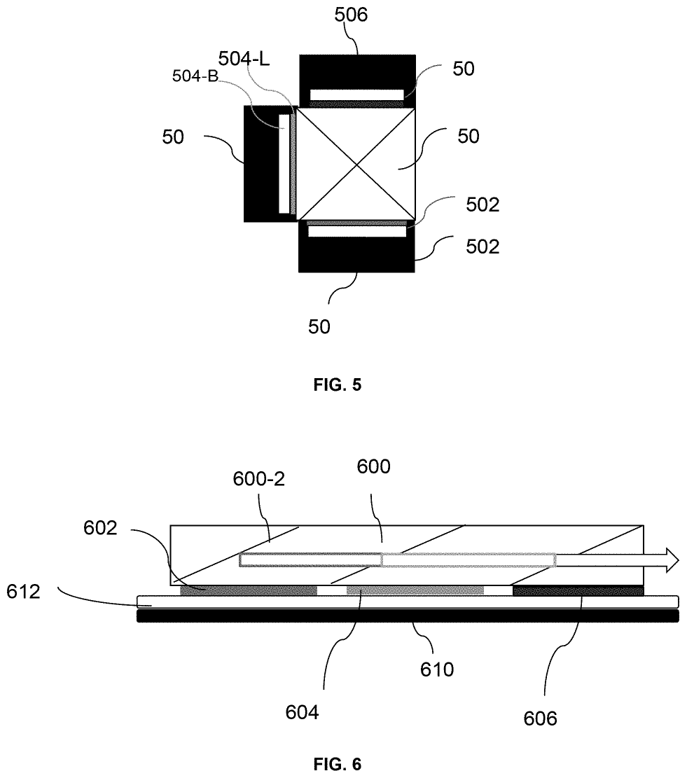

FIG. 5 shows another approach to make color devices. Here, a dichroic prism 500 is used to combine the light from three mono colour devices 502 504, 506. The mono colour devices can have a frontplane 502-L, 504-L, and 506-L for creating the light and backplane 502-B, 504-B, and 506-G for controlling the light output per pixel. Also, mechanical structures 502M, 504M, and 506M are used for packaging, thermal management, or electrical connections. The challenge for this approach is that it is very bulky and not a good fit for wearable electronics such as augmented reality devices. The other challenge is that the devices need to be aligned very accurately which is difficult for high pixel density devices.

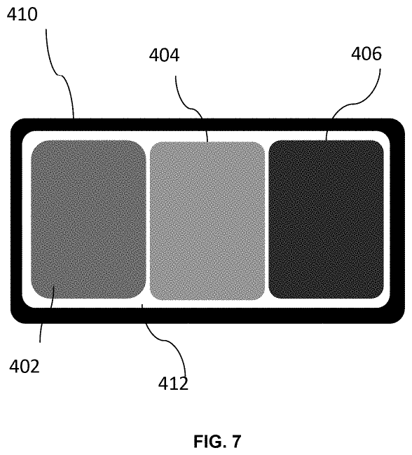

FIG. 6 introduces a new embodiment where a linear color combinator 600 is used to combine the color from different sources 602, 604, and 606. Here, the sources (image array) are on one side of the light combinator. The light generated by either of the light sources is redirected to the same direction using a reflector 600-2. The reflector also allows the image from previous source pass through. Here, the image sources can be a different type of light emitting devices such as microLED and/or OLED. A single backplane 612 can be used for driving the frontplane associated with each image source. The driving and interfaces can be shared in such cases. In other cases, different backplanes can be used for at least two different frontplanes. Here, the combination of frontplane and backplane can be secured on a mechanical structure. Here, the alignment conies from the position accuracy of the image sources on the backplane (or mechanical structure). As a result, high alignment accuracy can be achieved without significant overhead. Furthermore, the combined structure is very compact on all three dimensions. Here, another image source can be also set on the back surface 600-8. In one case, the image source here can be an image sensor capturing the lights that pass through from the other side 600-10. This sensor can be used for tracking functionality, imaging, and so on. One of the other image sources can be creating lights for this image sensor. The two sides 600-8 and 600-10 can be physical structure or just virtual surfaces.

In one case, the reflector 600-2, 600-4, and 600-6 can be dichroic mirrors (or prisms). Here, the mirror reflects the light below a cutoff wavelength and passes the lights within a bandwidth. The arrangement can be different if the image source is a sensor or a display. The following is for display applications, but the same principle can be used to develop setup for sensors. The following setup is for 3 light sources, but similar arrangement can be used for more image sources. The assumption is that the wavelength generated by image source 602 is between W2L and W2H (W2L <W2H) where W2L and W2H defines the passing bandwidth of the mirror, image source 604 is between W4L and W4H (W4L <W4H), and by image source 606 is between W6L and W6H (W4L <W4H). The mirror 600-2 cutoff wavelength is larger than W2H (one can use smaller than W2H to cut some of unwanted wavelengths from the image source). The mirror 600-4 cutoff wavelength is between W2L and W4H (W4H <W2L) (one can use smaller than W4H to cut some of unwanted wavelengths from the image source). The mirror 600-6 cutoff wavelength is between W4L and W6H (W6H <W4L) (one can use smaller than W4H to cut some of unwanted wavelengths from the image source). Here, the mirror 600-2 reflects a part of the light generated by light source 602. The mirror 600-4 reflects a part of the light generated by light source 604 and passes part of the light coming from the mirror 600-2. The mirror 600-6 reflects a part of the light generated by light source 606 and passes part of the lights coming from the mirror 600-4. If the light from the sources has overlap in wavelength, the selection of cutoff wavelength can be done based on the optimization of color point or power consumption or other parameters.

The reflector can be made of different optical layers with different optical properties or made out of grating structure.

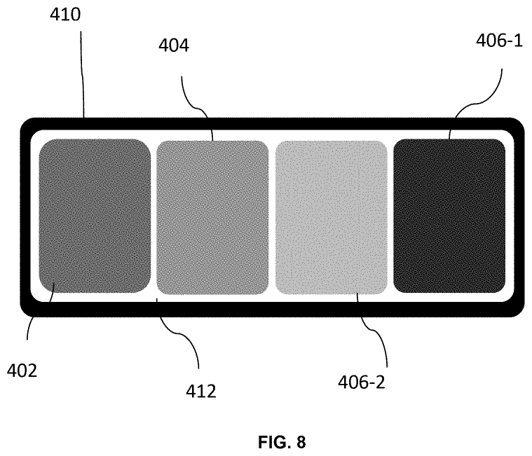

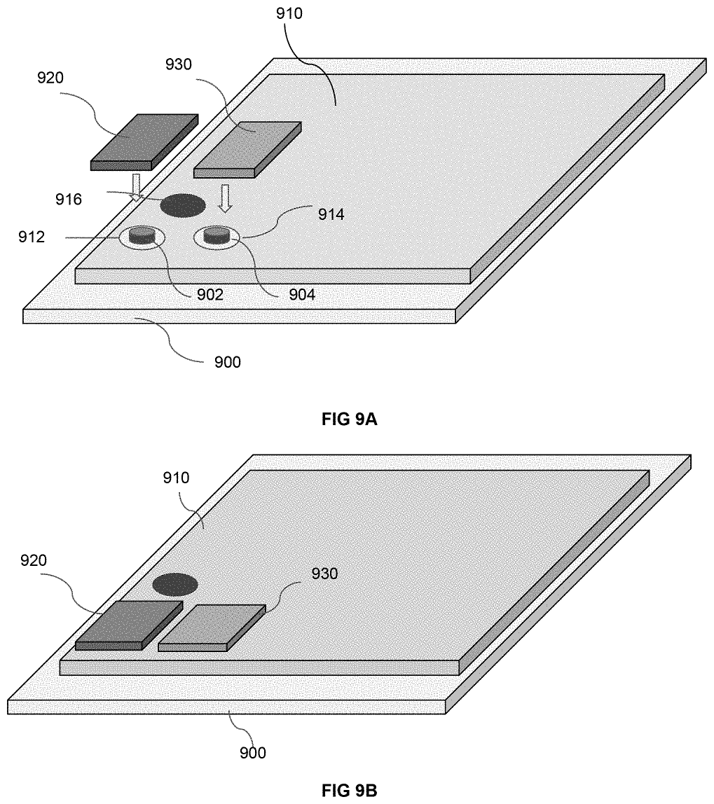

FIG. 7 shows a top view of an exemplary image source 402, 404, 406 arrangement. The front planes are located on backplane(s) 412. A mechanical structure can be used for holding the structure in place and providing connection to the backplane. The mechanical structure can be part of the final applications (e.g. Augmented reality headset).

One unique advantage of this embodiment is that it allows the integration of several image sources and is not limited to two or three. As a result, different images sources can be integrated to provide better power efficiency, more user friendly performance and different functionality. In one case, two types of image source can be used for at least one of the image sources: one with very high color purity and the other one with better power or user friendly performance. For example, in the case of blue, the pure blue light at high intensity can be harmful to users' eyes. As a result, two image sources can be used one with pure blue 406-1 and the other one with lighter blue 406-2. For the majority of the cases where blue light is needed, light blue image source 406-2 is used. Only when pure blue is needed, one can activate the pure blue image source 406-1. Generally, the light blue has higher power efficiency which in turn can offer lower power consumption. The same can be used for other image sources as well.

In another embodiment, the same or different image sources can be used with less than one pixel offset, respectively. As a result, when both are used together, it can offer much higher resolution images.

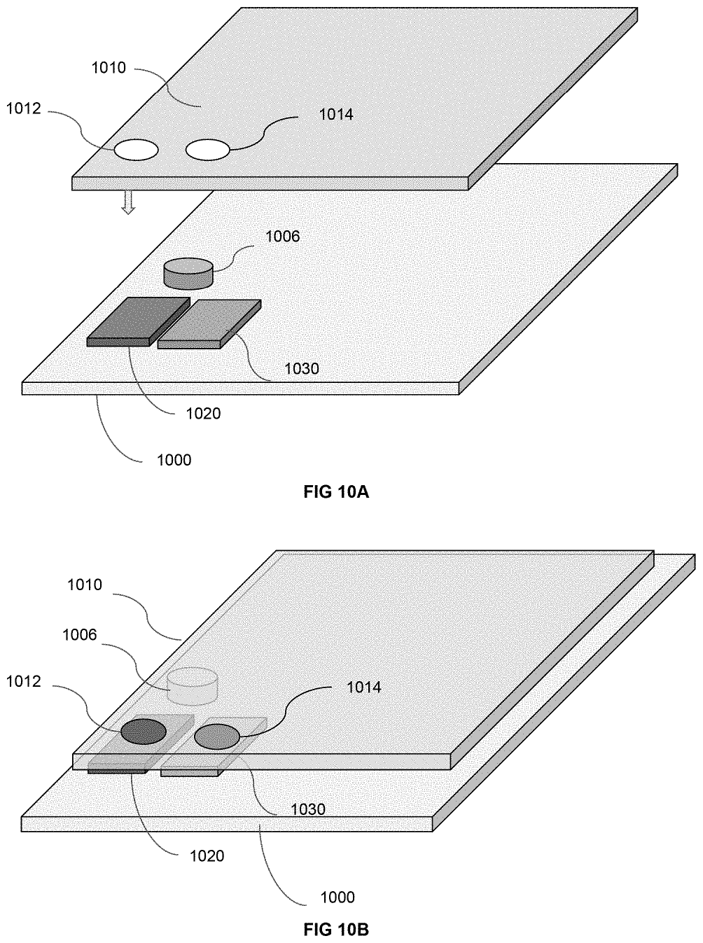

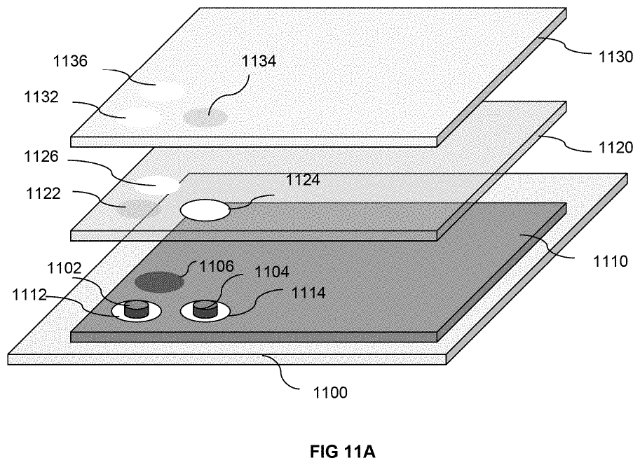

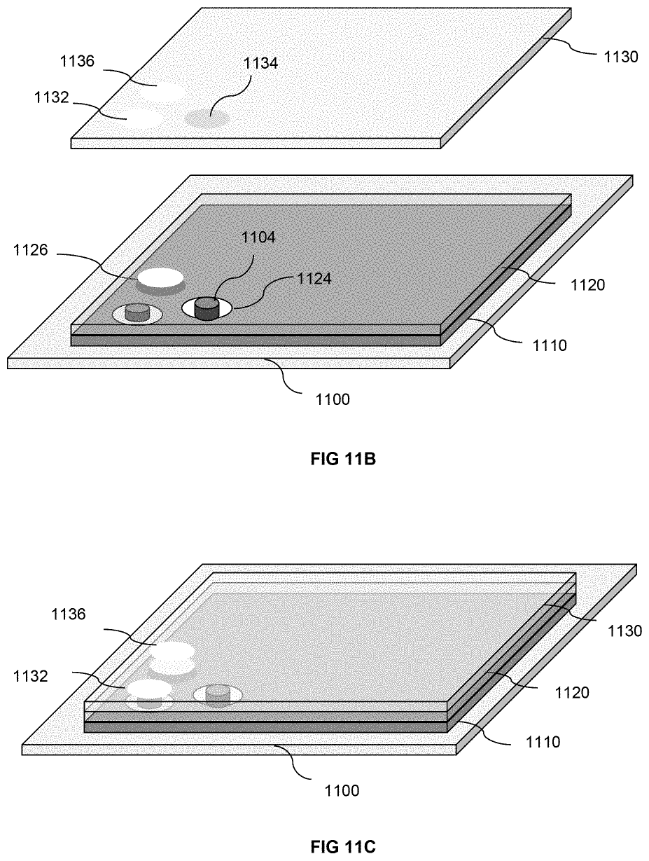

In another embodiment demonstrated in FIGS. 9A and 9B, one of the microdevices (array) 916 is formed as continuous pixelation where the current is confined into small areas of the stacked layers of semiconductor 910 in at least one area to create an isolated micro device effect (there can be an array of this current confinement structure to form an array of the micro devices). In one example, these stack layers can be the red epitaxial light emitting layers. The stacked layers 910 are bonded to a backplane 900 where the pads in the backplane define the sub pixels. Here, there can be post processing performed on the stacked layer 910 to further isolate the sub pixels (array) 916. The backplane 900 may have multiple sub pixels for each pixel in an array of pixels. There can be a pad for each subpixel and the current confinement structure (array) is bonded to the associated pads in the backplane sub pixel. There can be more than one current confinement structure associated with the pad in the backplane. The post processing can include current confinement, etching one or more of the top layers in the stacked layers 910. In one case, the stacked layers may have VIA's 912 and 914 before bonding to the backplane. The VIA's can be at least partially filled with a conductive layer separated from the walls of the VIA with a dielectric. The connection can couple a pad from the backplane to the top of the stack layer. In another case, electrical VIA's 912 and 914 are formed in the stacked layers 910 after the stacked layers 910 are bonded into the backplane. This process enables proper alignment of the opening with the pads in the other sub pixels in the backplane. The sidewall of the VIA's 912 and 914 can be passivated and pads 902 and 904 are formed either inside the VIA's 912 and 914 or on the walls of the VIA's 912 and 914. Micro devices 920 and 930 are bonded to the pads. There can be more than one pads or more than two VIAS for each micro device. A conductive layer can be deposited on top of the micro devices 920 and 930 or the stacked layer 910.

In another embodiment demonstrated in FIGs' 10A and 10B, one of the microdevices (array) 1016 is formed as continuous pixelation where the current is confined into the stacked layers of semiconductor 1010 in at least one area to create an isolated micro device effect (there can be an array of this current confinement structure to form an array of the micro devices). In one example, these stack layers can be the red epitaxial light emitting layers. The stacked layers 1010 are bonded to a backplane 1000 where the pads in the backplane define the sub pixels. Here, there can be post processing performed on the stacked layer 1010 to further isolate the sub pixels (array) 1016. The backplane 1000 may have multiple sub pixels for each pixel in an array of pixels. There can be a pad 1006 for each subpixel and the current confinement structure (array) is bonded to the associated pads in the backplane sub pixel. There can be more than one current confinement structure associated with the pad 1006 in the backplane. The post processing can include current confinement, etching one or more of the top layers in the stacked layers 1010.

In one case, the stacked layers may have VIA's 1012 and 1014 before bonding to the backplane. The VIA is to allow the light from the micro devices placed on the backplane pass through the stack layer 1010 (or the signal gets to the micro devices on the backplane). In another case, optical VIA's 1012 and 1014 are formed in the stacked layers 1010 after the stacked layers 1010 is bonded into the backplane. This process enables proper alignment of the opening with the micro devices 1020 and 1030 in the other sub pixels in the backplane. The sidewall of the VIA's 1012 and 1014 can be passivated and reflective layers formed on the walls. Micro devices 1020 and 1030 are bonded to the backplane prior to the bonding of the stacked layers 1010. There can be more than one pads or more than two VIA's for each micro device. A conductive layer can be deposited on top of the micro devices 1020 and 1030 or the stacked layer 1010.

The bump 1006 can also include a microdevice similar to 1020 or 1030. Here, the microdevice can be formed to couple the backplane to a pad formed on top of the device. In another case, the array of microdevices 1020 and 1030 bonded to the backplane is tested. Before allocating a microdevice to form a bump 1006, the defective types are identified, and the set allocated for the bump will include some of the defective microdevices.

In another case, the stacked layer with current confinement is formed on the bonded microdevices on the backplane using other methods such as deposition. Here, planarization layers can be used to planarize the surface of the backplane with the microdevice and the stacked layers are formed on the planarization layer.

In another embodiment demonstrated in FIGs' 11A and 11B and I IC, more than one microdevices (array) 1106, 1122, and 1134 are formed as continuous pixelation where the current is confined into the stacked layers of semiconductor 1110, 1120, and 1130 in at least one area to create an isolated micro device effect (there can be an array of this current confinement structure to form an array of the micro devices). In one example, these stack layers can be the red, green or blue epitaxial light emitting layers. The stacked layers 1110 is bonded to a backplane 1100 where the pads in the backplane define the sub pixels. Here, there can be post processing performed on the stacked layer 1110 to further isolate the sub pixels (array) 1116. The backplane 1100 may have multiple sub pixels for each pixel in an array of pixels. There can be a pad for each subpixel and the current confinement structure (array) 1106 is bonded to the associated pads in the backplane sub pixel. There can be more than one current confinement structure associated with each associated pad in the backplane. The post processing can include current confinement, etching one or more of the top layers in the stacked layers 1110. In one case, the stacked layers may have electrical VIA's 1112 and 1114 before bonding to the backplane. The VIA couples the associated pads 1102 and 1104 to the stack layer 1110 (or the signal gets to the micro devices on the backplane). In another case, electrical VIA's 1112 and 1114 are formed in the stacked layers 1110 after the stacked layers 1110 is bonded into the backplane. This process enables proper alignment of the opening with the micro devices in stacked layers 1120 and 1130 in the other sub pixels in the backplane. The sidewall of the VIA's 1112 and 1114 can be passivated and conductive layers formed on the walls.

The stacked layers 1120 are bonded to a backplane 1100 on top of the stacked layer 1110 where the pads in the backplane define the sub pixels. Here, there can be post processing performed on the stacked layer 1120 to further isolate the sub pixels (array) 1122. The backplane 1100 may have multiple sub pixels for each pixel in an array of pixels. There can be a pad for each subpixel and the current confinement structure (array) 1122 is bonded to the associated pads in the backplane sub pixel. There can be more than one current confinement structure associated with each associated pad in the backplane. The post processing can include current confinement, etching one or more of the top layers in the stacked layers 1120. In one case, the stacked layers 1120 may have electrical VIA's 1124 and optical VIA's 1126 before bonding to the backplane. The electrical VIA couples the associated pads 1104 to the stack layer 1130. The optical VIA allows the lights from the microdevice in stacked layer 1110 to pass through the stacked layer 1120 (or the signal gets to the micro devices on the layer 1110). In another case, electrical VIA's 1124 and optical VIA's 1126 formed in the stacked layers 1120 after the stacked layers 1120 is bonded into the backplane. This process enables proper alignment of the opening with the micro devices in stacked layers 1110 and 1130 in the other sub pixels in the backplane. The sidewall of the VIA 1124 can be passivated and conductive layers formed on the walls or a pad from inside the VIA 1124. The sidewall of the VIA 1126 can be coated with passivation and reflective layers.

The stacked layers 1130 are bonded to a backplane 1100 on top of the stacked layer 1120 where the pads in the backplane define the sub pixels. Here, there can be post processing performed on the stacked layers 1130 to further isolate the sub pixels (array) 1134. The backplane 1100 may have multiple sub pixels for each pixel in an array of pixels. There can be a pad for each subpixel and the current confinement structure (array) 1134 is bonded to the associated pads in the backplane sub pixel. There can be more than one current confinement structure associated with each associated pad in the backplane. The post processing can include current confinement, etching one or more of the top layers in the stacked layers 1130. In one case, the stacked layers 1130 may have optical VIA's 1132 and 1136 before bonding to the backplane. The optical VIA allows the lights from the microdevice in stacked layers 1110 and 1120 to pass through the stacked layer 1130 (or the signal gets to the micro devices on the layer 1110 and 1120). In another case, the optical VIA's 1136 and 1132 are formed in the stacked layers 1130 after the stacked layers 1130 is bonded into the backplane 1100. This process enables proper alignment of the opening with the micro devices in stacked layers 1110 and 1120 in the other sub pixels in the backplane. The sidewall of 1132 and 1136 can be coated with passivation and reflective layers.

Micro devices 1020 and 1030 are bonded to the backplane prior to the bonding of the stacked layers 1010. There can be more than one pads or more than two VIA's for each micro device. A conductive layer can be deposited on top of the micro devices 1020 and 1030 or the stacked layer 1010.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

We claim:

1. A microdevice array having a microdevice comprising:
stacked layers of a semiconductor bonded to a backplane;
pads in the backplane defining sub pixels, with multiple sub pixels for a pixel in an array of pixels; and
the stacked layers bonded to the pads in the backplane defining sub pixels.

2. The microdevice array of claim 1, where there are more than one set of stacked layers associated with the pads in the backplane defining sub pixels.

3. The microdevice array of claim 1, wherein one or more of top layers in the stacked layers are etched.

4. The microdevice array of claim 1, wherein the stacked layers have VIA's before bonding to the backplane.

5. The microdevice array of claim 4, wherein the VIA's are at least partially filled with a conductive layer separated from walls of the VIA's with a dielectric.

6. The microdevice array of claim 4, wherein the VIA's couple a pad from the backplane to the top of the stack layer.

7. The microdevice array of claim 1, wherein electrical VIA's are formed in the stacked layers after the stacked layers are bonded into the backplane.

8. The microdevice array of claim 7 wherein the VIA's are aligned with the pads in the other sub pixels in the backplane.

9. The microdevice array of claim 8, wherein VIA's have passivated sidewalls and the pads are either inside the VIA's or on the walls of the VIA's.

10. The microdevice array of claim 9, wherein additional microdevices are bonded to the pads.

11. The microdevice array of claim 10, wherein there are more than one pads or more than two VIAs for each micro device.

12. The microdevice array of claim 10, wherein the micro devices or stacked layers have a conductive layer on top.

13. The microdevice array of claim 1, wherein the stacked layers are red epitaxial light emitting layers.

14. The microdevice array of claim 4, wherein the VIA's are optical.

15. The microdevice array of claim 7, wherein electrical VIA's are optical.

16. The microdevice array of claim 15, wherein the VIA's are aligned with the pads in the other sub pixels in the backplane.

17. The microdevice array of claim 16, wherein VIA's have passivated sidewalls with reflective layers on the sidewalls.

18. The microdevice array of claim 17, wherein additional microdevices are bonded to the pads.

19. The microdevice array of claim 18, wherein there are more than one pads or more than two VIAs for each micro device.

20. The microdevice array of claim 18, wherein the micro devices or stacked layers have a conductive layer on top.

21. The microdevice array of claim 19, wherein a bump comprising a microdevice couples the backplane to a pad formed on top of the microdevice.

22. The microdevice array of claim 1, wherein the microdevice array is a part of more than one microdevice array.

23. The microdevice array of claim 22, wherein the stacked layers are red, green, or blue epitaxial light emitting layers.

24. The microdevice array of claim 7, wherein the VIA's are aligned with the additional microdevices in additional stacked layers and the pads in the other sub pixels in the backplane.

25. The microdevice array of claim 22, wherein a second stacked layer is bonded to the backplane on top of a first stacked layer where the pads in the backplane define the sub pixels.

26. The microdevice array of claim 25, wherein one or more of top layers in the second stacked layers are etched.

27. The microdevice array of claim 25, wherein the second stacked layer has electrical and optical VIA's before bonding to the backplane.

28. The microdevice of claim 27, wherein the electrical VIA couple associated pads to a third stacked layer.

29. The microdevice array of claim 25, wherein the second stacked layer has electrical and optical VIA's after bonding the second stacked layer to the backplane.

30. The microdevice array of claim 29, wherein the VIA's are aligned with the additional microdevices in the first and third stacked layers and the pads in the other sub pixels in the backplane.

31. The microdevice array of claim 27, wherein electrical VIA's have passivated sidewalls and conductive layers formed on the walls or a pad from inside the electrical VIA.

32. The microdevice array of claim 27, wherein optical VIA's have passivated sidewalls with reflective layers on the sidewalls.

33. The microdevice array of claim 22, wherein the third stacked layer is bonded to the backplane on top of the second stacked layer where the pads in the backplane define the sub pixels.

34. The microdevice array of claim 33, wherein the third stacked layers have optical VIA's before bonding to the backplane.

35. The microdevice array of claim 33, wherein the third stacked layers have optical VIA's after bonding to the backplane.

36. The microdevice array of claim 35, wherein the VIA's are aligned with microdevices in first and second stacked layers and the pads in the other sub pixels in the backplane.

37. The microdevice array of claim 36, wherein VIA's have passivated sidewalls with reflective layers on the sidewalls.

38. The microdevice array of claim 33, wherein the microdevices in the second and third stacked layers are bonded to the backplane prior to the bonding of the first stacked layers.

39. The microdevice array of claim 33, wherein there is a conductive layer on top of the microdevices of the second and third stacked layers or the first stacked layer.

40. The microdevice array of claim 33, wherein there are more than one pads or more than two VIA's for each microdevice.

41. A method to modulate resistance in a color microdevice array, the method comprising:
having more than one type of microdevices per pixel;
sharing at least one type of microdevice between two adjacent pixels; and
modulating a resistance of contact layers of the microdevice to create pixelation.

42. The method of claim 41, wherein a pixel orientation is different for the adjacent pixels enabling sharing of at least one microdevice between at least two adjacent pixels.

43. The method of claim 42, wherein a color diffuser is used per pixel to reduce the effect of a pixel orientation variation.

44. A method to fabricate a color microdevice array, the method comprising:
stacking more than one layer of monolithic device on top of a backplane;
bonding a first monolithic device to the backplane through a first pad;
forming an opening in the first monolithic device;
forming a second pad in the opening in the first monolithic device; and
bonding a second monolithic device to the backplane through the second pad.

45. The method of claim 44, wherein a pixelation in at least one of the layers is formed by modulating the resistance of the contact layers between the pads.

46. A method to combine light colors in a color microdevice array, the method comprising:
combining light colors from different image sources using a linear color combinator;
having the image sources on one side of linear color combinator;
redirecting light generated by different image sources using a reflector;
having a frontplane for image sources to produce or capture a light per pixel;
having a backplane for controlling or extracting the output of the frontplane per pixel; and
coupling the image sources to fewer than two surfaces of the linear color combinator.

47. The method of claim 46, wherein the image sources are coupled to one surface of the linear color combinator.

48. The method of claim 47, wherein the frontplane of the image sources are formed/bonded to one backplane.

49. The method of claim 46, wherein the backplane is bonded to a mechanical structure.

50. The method of claim 26, wherein the reflector is made of different optical layers with different optical properties or made out of grating structure.

51. The method of claim 46, wherein an additional image source is set on a back surface and acts as an image sensor to capture lights that pass through the other side.

52. The method of claim 51, wherein an additional image source, that is not the sensor, acts as a light producer for the image sensor.

53. The method of claim 46, wherein the reflector is a dichroic mirror.

54. The method of claim 53, wherein the dichroic mirror reflects the light below a cutoff wavelength and passes the lights within a bandwidth.

55. The method of claim 54, wherein the image source is a display.

56. The method of claim 54, wherein more than one light source is used for image sources for more than one reflectors such that a first reflector reflects part of a light generated by a first light source, and a second reflector reflects part of a light generated by a second light source and passes part of the light coming from the first reflector.
